(19) United States
(12) Patent Application Publication
(10) Pub. No.: US 2008/0083926 A1
(43) Pub. Date: Apr. 10, 2008

(54) Printing device structures using nanoparticles

(75) Inventor: Toni Ostergard, Turku (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: Nokia Corporation

(21) Appl. No.: 11/546,026

(22) Filed: Oct. 10, 2006

(51) Int. Cl. H01L 29/06; H01L 21/36

(52) U.S. Cl. 257/64; 977/773; 977/887; 438/149; 438/478

(57) ABSTRACT

The specification and drawings present a new apparatus and method for printing transistor or diode structures using nanoparticles (e.g., silicon nanoparticles). Si-based electronic structures (e.g., transistors, diodes) can be printed in a simple low cost process and thus being a potential alternative to obtain a low cost manufacturing process for, e.g., Si-based active matrix (AM) backplanes as well as other applications.

### TECHNICAL FIELD

The present invention relates generally to electronic devices and, more specifically, to printing transistor or diode structures using nanoparticles (e.g., Si nanoparticles).

### BACKGROUND ART

One of the commonly used display technologies e.g. in mobile devices today is active-matrix (AM) Liquid Crystal Display (LCD) technology. The technology is also used in laptops, personal computer monitors, televisions, etc. The technology is well known, and the pixel driving in the displays is “based” on the well known silicon (Si) transistor structure based, e.g., on a-Si, Low Temperature PolySilicon (LTPS), Continuous-Grain Silicon (CGS), etc.

However, the manufacturing costs of the active matrix (AM) backplanes (i.e., the substrate with the transistor structures and conducting lines) for displays may be relatively expensive. Furthermore, the processing parameters related to the formation Si transistors onto the substrate by processing of the deposited Si thin film and thin-film transistor (TFT) structures may not be optimal for certain substrates such as polymer (plastic) based substrates. AM-backplanes can be manufactured onto plastic substrates, but the manufacturing process is very challenging, and additional cost may be the penalty (still in a research phase). The use of plastic based substrates may have several benefits, such as more durable displays, flexible/bendable/conformable displays providing more design freedom, which are all driving the development of plastic based LCDs.

Considering the cost issues of the AM-backplane manufacturing, as well as the compatibility issue with plastic based substrates, it is natural that researchers have been looking for alternative solutions to obtain AM-backplanes. One approach that has extensively been investigated is the use of organic based semiconductors, i.e., conjugated molecules and polymers with semiconducting properties. Such organic semiconducting materials are well known and various types of materials are used, e.g., in Organic Light Emitting Diodes/Displays (OLED) but also in Organic Transistors such as organic TFTs (OTFTs) and organic field effect transistors (OFETs). Recently, these organic transistors have been seen as a potential alternative to Si in AM-backplanes.

The organic transistors are still in the research phase, but some researchers and companies expect the technology to provide significant benefits compared to Si in a long run, especially in relatively simple applications such as AM-backplanes. The main reason why organic transistors are extremely promising is the ease of manufacturing that the use of organic semiconductors can provide. Since the organic materials can be solution processed, it is expected that the transistors can be printed, e.g. by ink-jet printing, onto basically any substrate in a simple and low cost manufacturing process.

Printing of organic transistors has already been extensively demonstrated, e.g., in active matrix backplanes for flexible displays (see, e.g., Polymer Vision: http://www.polymervision.com/, downloaded Sep. 7, 2006), and mass-manufacturing processes are currently being developed.

Although the performance of printed organic transistors may not be able to compete with the best Si-transistors, the simple manufacturing technique is expected to bring such huge benefits that the technology will eventually be capable of replacing Si in certain applications. One such application is expected to be the AM backplane used for displays. The processing of Si into transistors is simply expected to be too expensive compared to the simple printing of organic transistors (in certain applications).

However, the conclusion that Si-based AM-backplanes will not be competitive in the long run is based on the assumption that Si-transistors cannot be printed in a similar simple fashion as organic transistors, which so far has also been the case.

### DISCLOSURE OF THE INVENTION

According to a first aspect of the invention, an apparatus, comprises: a substrate; and at least one transistor or diode structure disposed on the substrate, wherein the at least one transistor or diode structure comprises: at least one semiconductor region comprising nanoparticles doped with p or n impurities and disposed using printing.

According further to the first aspect of the invention, the at least one transistor or the diode structure may comprise at least one further semiconductor region comprising undoped nanoparticles.

According further to the first aspect of the invention, the nanoparticles may be silicon nanoparticles. Further, the silicon nanoparticles may have a size in a range of one to one hundred nanometers.

Still further according to the first aspect of the invention, the at least one semiconductor region may have a predetermined level of doped n or p impurities.

According further to the first aspect of the invention, the at least one transistor or diode structure may be a bipolar transistor and the at least one semiconductor region may comprise three semiconductor regions with nanoparticles forming pn junctions, each the semiconductor region having a different concentration of the n or p impurities and disposed using the printing.

According still further to the first aspect of the invention, the substrate may be made of one of: a) a dielectric material, and b) a plastic material.

According still further to the first aspect of the invention, the at least one transistor or diode structure may be a metal-oxide-semiconductor field-effect transistor or a pn junction diode.

According yet further still to the first aspect of the invention, before the disposing, the nanoparticles may be formed and a solution may be formed with the nanoparticles, and the printing may be performed using the solution comprising the nanoparticles.

Yet still further according to the first aspect of the invention, the printing may be one of: a) an ink-jet printing, and b) an ink-jet printing, wherein an ink-jet printer system/ink head is combined with an ultra sound generator.

Still yet further according to the first aspect of the invention, the apparatus may comprise at least one electrode made of a conducting material for making an electrical contact with the at least one semiconductor region, wherein the at least one electrode may be disposed on: a) the at least one semiconductor region after the at least one semiconductor region is printed, and b) on the substrate before the at least one semiconductor region is printed.

Still further still according to the first aspect of the invention, after disposing, the at least one semiconductor region may be thermally annealed for improving a connection between the nanoparticles. Further, before the annealing, the at least one semiconductor region may be surface-activated by a metal for reducing a temperature for annealing.

According further still to the first aspect of the invention, the at least one semiconductor region may be further filled with a filler material for improving a connection between the nanoparticles. Further, the filler material may be a conducting material, a semiconducting organic material or a polymer.

According yet further still to the first aspect of the invention, all components of the at least one transistor or diode structure may be disposed on the substrate using the printing.

According still yet further to the first aspect of the invention, the at least one transistor or diode structure may be a part of an active matrix backplane of a liquid crystal display.

According to a second aspect of the invention, a method, comprises: disposing at least one transistor or diode structure on a substrate, wherein the at least one transistor or diode structure comprises: at least one semiconductor region comprising nanoparticles doped with p or n impurities and disposed using a printing technique.

According further to the second aspect of the invention, the at least one transistor or the diode structure may comprise at least one further semiconductor region comprising undoped nanoparticles.

Further according to the second aspect of the invention, the nanoparticles may be silicon nanoparticles.

Still further according to the second aspect of the invention, the at least one transistor or diode structure may be a bipolar transistor and the at least one semiconductor region may comprise three semiconductor regions with nanoparticles forming pn junctions, each the semiconductor region having a different concentration of the n or p impurities and disposed using the printing.

According further to the second aspect of the invention, the at least one transistor or diode structure may be a metal-oxide-semiconductor field-effect transistor or a pn junction diode.

According still further to the second aspect of the invention, before the disposing, the nanoparticles may be formed and a solution may be formed with the nanoparticles, and the printing may be performed using the solution comprising the nanoparticles.

According further still to the second aspect of the invention, after disposing, the at least one semiconductor region may be thermally annealed for improving a connection between the nanoparticles.

According to a third aspect of the invention, an electronic device, comprises: a) a module comprising: a substrate; and at least one transistor or diode structure disposed on the substrate, wherein the at least one transistor or diode structure comprises: at least one semiconductor region comprising nanoparticles doped with p or n impurities and disposed using a printing technique; and b) a component comprising the module.

Further according to the third aspect of the invention, the component may be a liquid crystal display and the module may be an active matrix backplane of the liquid crystal display.

Still further according to the third aspect of the invention, the at least one transistor or the diode structure may comprise at least one further semiconductor region comprising undoped nanoparticles.

According further to the third aspect of the invention, the nanoparticles may be silicon nanoparticles.

According still further to the third aspect of the invention, the at least one transistor or diode structure may be a bipolar transistor and the at least one semiconductor region may comprise three semiconductor regions with nanoparticles forming pn junctions, each the semiconductor region having a different concentration of the n or p impurities and disposed using the printing.

According yet further still to the third aspect of the invention, the at least one transistor or diode structure may be a metal-oxide-semiconductor field-effect transistor or a pn junction diode.

According further still to the third aspect of the invention, before the disposing, the nanoparticles may be formed and a solution may be formed with the nanoparticles, and the printing may be performed using the solution comprising the nanoparticles.

According to a fourth aspect of the invention, an apparatus, comprises: means for depositing; and at least one means for an electronic conversion disposed on the substrate, wherein the at least means for an electronic conversion comprises: at least one semiconductor region comprising nanoparticles doped with p or n impurities disposed using a printing technique.

According further to the fourth aspect of the invention, the means for depositing may be a substrate and the at least one means for an electronic conversion may be at least one transistor or diode structure.

### BRIEF DESCRIPTION OF THE DRAWINGS

For a better understanding of the nature and objects of the present invention, reference is made to the following detailed description taken in conjunction with the following drawings, in which:

FIGS. 1a and 1b are schematic representations (side and top views, respectively) of a printed Si-based p-n-p bipolar transistor with electrodes on top of a Si print, according to an embodiment of the present invention;

FIG. 2 is a schematic representation (side view) of a printed Si-based p-n-p bipolar transistor with electrodes under a Si print, according to an embodiment of the present invention;

FIG. 3 is a flow chart for printing a transistor or diode structure using nanoparticles (e.g., Si nanoparticles), according to an embodiment of the present invention; and

FIG. 4 is a schematic representation of an electronic device utilizing a component manufactured using printing transistor or diode structures with nanoparticles (e.g., Si nanoparticles), according to embodiments of the present invention.

### MODES FOR CARRYING OUT THE INVENTION

A new method and apparatus are presented for printing transistor or diode structures using nanoparticles (e.g., silicon nanoparticles). According to embodiments of the present invention, Si-based electronic structures (e.g., transistors, diodes) can be printed in a simple low cost process and thus being a potential alternative to obtain a low cost manufacturing process for, e.g., Si-based active matrix (AM) backplanes as well as other applications such as processors requiring a very large-scale integration (VLSI) level integration and performance.

According to an embodiment of the present invention, the process can comprise:

Step 1: Formation of doped and un-doped nanoparticles (e.g., Si-nanoparticles);

Step 2: Formation of a solution with said nanoparticles; and

Step 3: Printing of various transistor or diode structures onto a substrate using solutions containing the Si-nanoparticles as well as other relevant materials, and printing of other relevant materials (e.g., conducting and insulating materials).

In step 1, the creation of nanoparticles (such as Si-nanoparticles) can be done, e.g., by an electrochemical etching of silicon wafers, as done by Professor Nayfeh's group at the University of Illinois (e.g., see Akcakir et al, “Detection of Luminescent Single Ultrsmall Silicon Nanoparticles Using Fluctuation Correlation Spectroscopy”, Applied Physics Letters, 76, pp. 1857-1859 2000; Chaieb et al., “Assemblies of Silicon Nanoparticles Roll up into Flexible Nanotubes”, Applied Physics Letters, 87, pp. 062104 2005).

Although Professor Nayfeh's group manufactures intrinsic (undoped) Si-nanoparticles primarily for optical applications (e.g., see Nayfeh M H, Rao S, Nayfeh O M, Smith A, and Therrien J, “UV Photodectors with Thin-Film Si Nanoparticle Active Medium”, IEEE Transactions on Nanotechnology 4, pp. 660-668, 2005, and Nayfeh O M, Rao S, Smith A, Therrien J, and Nayfeh, M H, “Thin Film Silicon Nanoparticle UV Detectors”, IEEE Photonics Technology Letters 16, pp. 1927-1929, 2004), the manufacturing technique may be extended to manufacturing of doped Si-nanoparticles as well, by starting with a doped Si-wafer. Other techniques to obtain doped and undoped Si-nanoparticles, such as mechanical grinding, can be utilized as well.

Step 2: although individual atoms/molecules of pure silicon may not be utilized for printing, extremely small particles of silicon, i.e., nanoparticles (ranging from approximately 1 mm to hundreds of nanometers, e.g., to one hundred nanometers) can be dispersed into a suitable solvent and printed, e.g., with an ink-jet printer. The use of ultrasound to obtain a dispersion of nanoparticles is well known and equipment for obtaining such dispersions is manufactured, e.g., by the company HIELSCHER (see http://www.hielscher.com/ultrasonics/index.htm, downloaded Sep. 7, 2006). The method is well known, e.g., in the printing industry for dispersing inks.

By combining an ultrasound disperser with an ink-jet printing head, the dispersed Si-nanoparticles can be printed in a simple printing process using a suitable solvent with an ultra sound generator continuously mixing the solution in the solution reservoir. However, other printing techniques such as Screen printing (with a higher concentration of active material in the “paste”), Gravure printing and others may be also used.

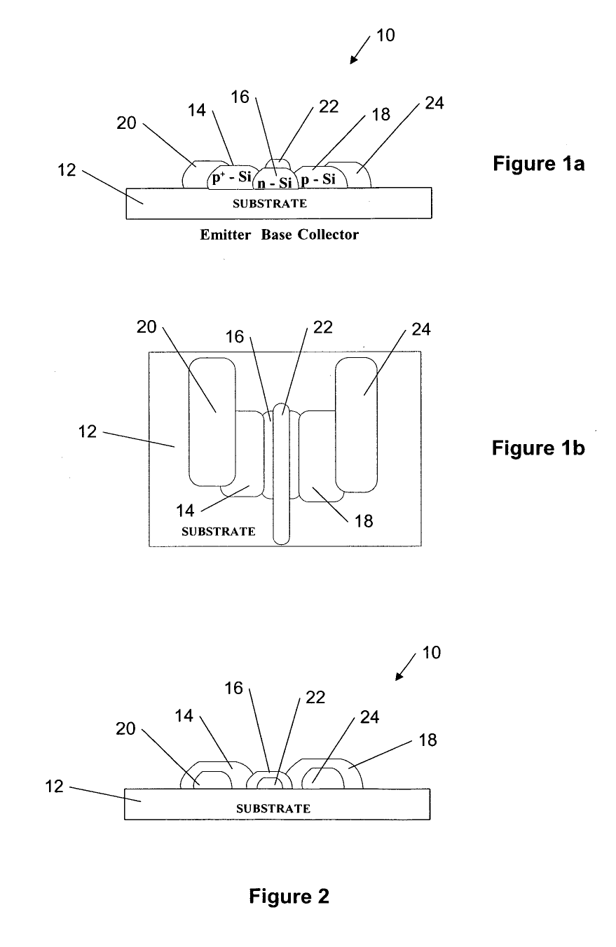

Step 3: by printing using the dispersed nanoparticles (e.g., Si-nanoparticles) with a suitable printing technique, one can obtain various transistor and diode structures on practically any substrate. In the case of an active matrix (AM) backplane for displays, the structure of main interest is a transistor structure. To obtain transistors (or other structures) suitable for the AM-backplane one can use several different approaches demonstrated in FIGS. 1a-1b and 2.

FIGS. 1a and 1b show an example among many others of schematic representations (side and top views, respectively) of a printed Si-based p-n-p bipolar transistor (which is a part of a module 10) with electrodes 20, 22 and 24 on top of a silicon print, according to an embodiment of the present invention. Here, in its simplest form, the p-n-p bipolar transistor could be formed by printing three parallel lines 14, 16 and 18 of p⁺, n, and p doped Si, respectively, on a substrate 12. In addition to the three printed lines 14, 16 and 18 of Si-nanoparticles, only the conducting lines 20, 22 and 24 that are connected to the p⁺, n and p regions, respectively, would be needed. The printing (e.g. by ink-jet, screen printing, etc.) of such conducting lines is also well known, e.g., by using an ink or a paste of a metal, carbon particles, conducting polymers, etc. In the example of FIGS. 1a and 1b, the conducting lines 20, 22 and 24 are printed after printing of the Si-nanoparticles lines 14, 16 and 18. FIG. 2 demonstrates another example of a further embodiment, wherein the conducting lines 20, 22 and 24 are printed first prior to the printing of the Si-nanoparticles lines 14, 16 and 18. Also, a combination of both approaches shown in FIGS. 1a-1b and FIG. 2 can be used, i.e., some electrodes can be printed before printing the Si-nanoparticles lines and other electrodes can be printed afterwards.

Thus, according to one embodiment of the present invention, all components of the transistor or diode structure can be disposed on the substrate using the printing technique.

Since devices made by printing nanoparticles (e.g., Si-nanoparticles) are based on the properties of Si and other materials, all different structures that have been demonstrated in these materials using the traditional lithography processes can be also possible to manufacture using printing as the manufacturing technique. Thus, other options to the bipolar transistor technology would be the MOSFET (Metal-Oxide-Semiconductor Field Effect Transistor) structures, either as NMOS(N-channel MOSFET), PMOS (p-channel MOSFET) or CMOS (Complementary MOSFET). Other alternatives may be (but are not limited to): pn junction diodes, e.g., Thin Film Diodes (TFD), AM-backplane applications, etc.

The various structures of MOSFETs and Diodes are well known to a person skilled in the art, and the structures (in their various configurations) could be realized by using printable nanoparticles (e.g., doped or undoped Si-nanoparticles), conducting materials (e.g., metal, carbon particles or conducting polymers), and various insulating materials (organic materials and/or inorganic oxides, e.g., in a form of nanoparticles).

By using the printing method, according to embodiments described herein, it is possible to print, e.g., Si-based transistors, as well as other electronic elements/components. However, the performance of said components may not be optimized due to a limited contact area between the individual nanoparticles. To improve the performance of the printed components two additional approaches, thermal annealing (or annealing by radiation at different wavelengths) and the use of an active “filler” material, can be used.

The thermal annealing (or even crystallization) can be performed by applying a direct heat, or by applying a laser light of an appropriate wavelength (a similar process that is used for obtaining low temperature poly silicon, LTPS). By annealing the nanoparticle based material, the connection between the individual nanoparticles and the device performance can be improved.

Furthermore, if the annealing temperature needs to be lowered, it is also possible to use surface activated Si-nanoparticles to reduce the energy required for the annealing process. Such surface activated Si-nanoparticles could have, e.g., Ni, Al, or other suitable metals on their surface (e.g., by electrochemically “attaching” metal atoms to the surface), i.e., said metals deposited as a separate layer that through diffusion at elevated temperatures is incorporated into, and interacting with the nanoparticles. Reducing the crystallization temperature in Si by using various metals (e.g., in the form of NiSi₂) is well known to a person skilled in the art.

By using an active “filler” material, the connection between the individual nanoparticles may also be improved. Such filler materials could be conducting and/or semiconducting organic molecules and/or polymers, and thus the approach would be more of a hybrid approach between, e.g., traditional Si-transistors and organic transistors (OTFTs). By blending the active “filler” material(s) in suitable portions with the Si-nanoparticle solution, the device performance may thus be improved. No thermal annealing would be needed then, which could be highly desirable if plastic based substrates are used. The printable “ink” would thus contain the nanoparticles, the active “filler” and the solvent. Furthermore, in line with the use of an active “filler” of, e.g., a conjugated polymer/molecular material, the printed structures may also be so called hybrid structures where some of the inorganic materials are completely replaced with organic counterparts. For example, in the transistor structures the insulating layer could be based on an organic insulator such as PMMA (polymethyl methacrylate) or its precursor, or another insulating polymeric material.

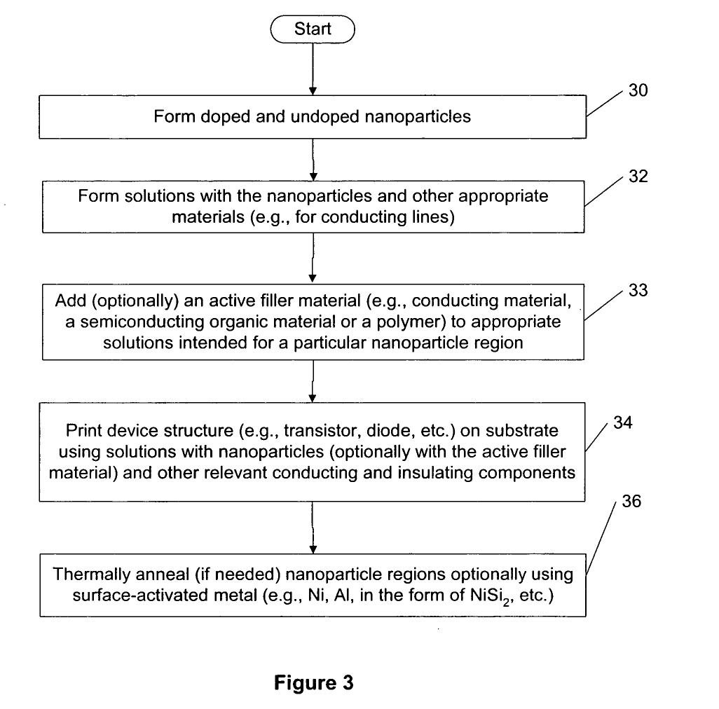

FIG. 3 shows a flow chart for printing a transistor or diode structure using nanoparticles (e.g., Si nanoparticels), according to an embodiment of the present invention.

The flow chart of FIG. 3 only represents one possible scenario among others. The order of steps shown in FIG. 3 is not absolutely required, so generally, the various steps can be performed out of order. In a method according to an embodiment of the present invention, in a first step 30, doped and undoped (if needed) semiconductor (e.g., Si) nanoparticles and possibly other relevant materials are formed for all components of the transistor or diode structure (including conduction lines, if appropriate). In a next step 32, solutions with the prepared nanoparticles are formed. In a next step 33, an active filler material (e.g., conducting material, a semiconducting organic material or a polymer) is added to an appropriate solution intended for a particular nanoparticle region. In a next step 34, a device structure (e.g., transistor, diode, etc.) is printed on the substrate using prepared solutions with semiconducting nanoparticles (optionally with the active filler material), and other relevant conducting and insulating components. Finally, in a step 36, nanoparticle regions are thermally annealed optionally using surface-activated metal (e.g., Ni, Al, in the form of NiSi2, etc.) for improving connections between nanoparticles.

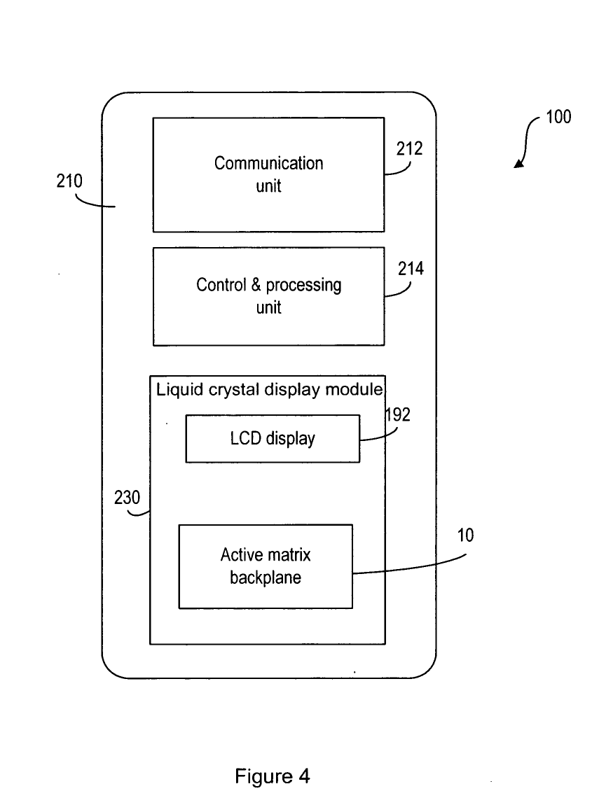

FIG. 4 shows an example of a schematic representation of an electronic device utilizing a module 10, AM backplane, manufactured using printing transistor or diode structures with nanoparticles (e.g., Si nanoparticles), according to embodiments of the present invention. The module 10 can be used in an electronic (e.g., portable or non-portable) device 100, such as a mobile phone, a computer, a monitor, a TV set, personal digital assistant (PDA), communicator, portable Internet appliance, digital video and still camera, a computer game device, and other electronic devices utilizing viewing. As shown in FIG. 4, the device 100 has a housing 210 to house a communication unit 212 for receiving and transmitting information from and to an external device (not shown). The device 100 also has a controlling and processing unit 214 for handling the received and transmitted information, and a liquid crystal display module 230 for viewing. The module 230 includes an LCD display 192 and the AM backplane 10. The controlling and processing unit 214 is operatively connected to the AM backplane 10 to provide image data to the LCD display 192 to display an image thereon.

It is to be understood that the above-described arrangements are only illustrative of the application of the principles of the present invention. Numerous modifications and alternative arrangements may be devised by those skilled in the art without departing from the scope of the present invention, and the appended claims are intended to cover such modifications and arrangements.

What is claimed is:

1. An apparatus, comprising:
a substrate; and
at least one transistor or diode structure disposed on said substrate, wherein said at least one transistor or diode structure comprises:
at least one semiconductor region comprising nanoparticles doped with p or n impurities and disposed using printing.

2. The apparatus of claim 1, wherein said at least one transistor or said diode structure comprises at least one further semiconductor region comprising undoped nanoparticles.

3. The apparatus of claim 1, wherein said nanoparticles are silicon nanoparticles.

4. The apparatus of claim 3, wherein said silicon nanoparticles have a size in a range of one to one hundred nanometers.

5. The apparatus of claim 1, wherein said at least one semiconductor region has a predetermined level of doped n or p impurities.

6. The apparatus of claim 1, wherein said at least one transistor or diode structure is a bipolar transistor and the at least one semiconductor region comprises three semiconductor regions with nanoparticles forming pn junctions, each said semiconductor region having a different concentration of said n or p impurities and disposed using said printing.

7. The apparatus of claim 1, wherein substrate is made of one of:
a) a dielectric material, and
b) a plastic material.

8. The apparatus of claim 1, wherein said at least one transistor or diode structure is a metal-oxide-semiconductor field-effect transistor or a pn junction diode.

9. The apparatus of claim 1, wherein, before said disposing, said nanoparticles are formed and a solution is formed with said nanoparticles, and said printing is performed using said solution comprising said nanoparticles.

10. The apparatus of claim 1, wherein said printing is one of: a) an ink-jet printing, and b) an ink-jet printing, wherein an ink-jet printer system/ink head is combined with an ultra sound generator.

11. The apparatus of claim 1, further comprising at least one electrode made of a conducting material for making an electrical contact with said at least one semiconductor region, wherein said at least one electrode is disposed on: a) said at least one semiconductor region after said at least one semiconductor region is printed, and b) on said substrate before said at least one semiconductor region is printed.

12. The apparatus of claim 1, wherein, after disposing, said at least one semiconductor region is thermally annealed for improving a connection between said nanoparticles.

13. The apparatus of claim 11, wherein, before said annealing, said at least one semiconductor region is surface-activated by a metal for reducing a temperature for annealing.

14. The apparatus of claim 1, wherein said at least one semiconductor region is further filled with a filler material for improving a connection between said nanoparticles.

15. The apparatus of claim 13, wherein said filler material is a conducting material, a semiconducting organic material or a polymer.

16. The apparatus of claim 1, wherein all components of said at least one transistor or diode structure are disposed on said substrate using said printing.

17. The apparatus of claim 1, wherein said at least one transistor or diode structure is a part of an active matrix backplane of a liquid crystal display.

18. A method, comprising:
disposing at least one transistor or diode structure on a substrate, wherein said at least one transistor or diode structure comprises:
at least one semiconductor region comprising nanoparticles doped with p or n impurities and disposed using a printing technique.

19. The method of claim 18, wherein said at least one transistor or said diode structure comprises at least one further semiconductor region comprising undoped nanoparticles.

20. The method of claim 18, wherein said nanoparticles are silicon nanoparticles.

21. The method of claim 18, wherein said at least one transistor or diode structure is a bipolar transistor and the at least one semiconductor region comprises three semiconductor regions with nanoparticles forming pn junctions, each said semiconductor region having a different concentration of said n or p impurities and disposed using said printing.

22. The method of claim 18, wherein said at least one transistor or diode structure is a metal-oxide-semiconductor field-effect transistor or a pn junction diode.

23. The method of claim 18, wherein, before said disposing, said nanoparticles are formed and a solution is formed with said nanoparticles, and said printing is performed using said solution comprising said nanoparticles.

24. The method of claim 18, wherein, after disposing, said at least one semiconductor region is thermally annealed for improving a connection between said nanoparticles.

25. An electronic device, comprising:
a) a module comprising:
a substrate; and
at least one transistor or diode structure disposed on said substrate,
wherein said at least one transistor or diode structure comprises:
at least one semiconductor region comprising nanoparticles doped with p or n impurities and disposed using a printing technique; and
b) a component comprising said module.

26. The electronic device of claim 25, wherein said component is a liquid crystal display and said module is an active matrix backplane of said liquid crystal display.

27. The electronic device of claim 25, wherein said at least one transistor or said diode structure comprises at least one further semiconductor region comprising undoped nanoparticles.

28. The electronic device of claim 25, wherein said nanoparticles are silicon nanoparticles.

29. The electronic device of claim 25, wherein said at least one transistor or diode structure is a bipolar transistor and the at least one semiconductor region comprises three semiconductor regions with nanoparticles forming pn junctions, each said semiconductor region having a different concentration of said n or p impurities and disposed using said printing.

30. The electronic device of 25, wherein said at least one transistor or diode structure is a metal-oxide-semiconductor field-effect transistor or a pn junction diode.

31. The electronic device of claim 25, wherein, before said disposing, said nanoparticles are formed and a solution is formed with said nanoparticles, and said printing is performed using said solution comprising said nanoparticles.

32. An apparatus, comprising:
means for depositing; and
at least one means for an electronic conversion disposed on said substrate, wherein said at least means for an electronic conversion comprises:
at least one semiconductor region comprising nanoparticles doped with p or n impurities disposed using a printing technique.

33. The apparatus of claim 32, wherein said means for depositing is a substrate and said at least one means for an electronic conversion is at least one transistor or diode structure
